(19) United States
(12) Patent Application Publication
(10) Pub. No.: US 2009/0166798 A1
(43) Pub. Date: Jul. 2, 2009

(54) DESIGN METHODOLOGY FOR GUARD RING DESIGN RESISTANCE OPTIMIZATION FOR LATCHUP PREVENTION

(75) Inventors: Phillip F. Chapman, Colchester, VT (US); David S. Collins, Williston, VT (US); Steven H. Voldman, South Burlington, VT (US)

Correspondence Address: SCULLY, SCOTT, MURPHY & PRESSER, P.C., 400 GARDEN CITY PLAZA, Suite 300, GARDEN CITY, NY, 11530, US

(73) Assignee: INTERNATIONAL BUSINESS MACHINES CORPORATION, Armonk, NY (US)

(21) Appl. No.: 11/964,337

(22) Filed: Dec. 26, 2007

(51) Int. Cl. H01L 29/00; G06F 17/50

(52) U.S. Cl. 257/503; 716/2; 257/E29.001

(57) ABSTRACT

A design structure is disclosed for a circuit optimizing guard ring design by optimizing the path resistance value between the components of the parasitic lateral bipolar transistors in a CMOS circuit and the power supply or ground. By comparing the calculated path resistance value to a maximum resistance number derived from specifications, elements that need further redesign are identified. Repeated redesign with several redesign options eventually lead to an optimized guard ring structure that provides area-efficient and sufficient latchup protection for the CMOS circuit. A design structure employing such an optimized guard ring is also provided.

### RELATED APPLICATIONS

The present application is related to a co-pending U.S. patent application Ser. No. 11/566,922 filed on Dec. 5, 2006, which is incorporated herein by reference.

### FIELD OF THE INVENTION

The present invention relates to semiconductor circuit design, and more particularly to a design structure for a circuit providing latchup prevention.

### BACKGROUND OF THE INVENTION

In typical CMOS circuitry, PFETs are built in an n-well formed within a P-substrate and NFETs are built in the P-substrate and outside the n-well. The drains of the PFETs and the n-well are both biased with a positive voltage supply, Vdd while the source of the NFETs and the P-substrate are both connected to ground. Between a neighboring pair of a PFET and an NFET, as can be found in a CMOS inverter for example, a parasitic p-n-p-n structure exists between the Vdd supply and ground formed by the PFET drain, the n-well, the P-substrate, and the NFET source due to their nature as doped semiconductor regions.

This parasitic p-n-p-n structure can be approximated to first order with an equivalent circuit comprising one pnp bipolar transistor, one npn bipolar transistor, and two resistors, wherein the base of the pnp bipolar transistor and the collector of the npn bipolar transistor share the same n-well, and the pnp bipolar transistor and the base of the npn bipolar transistor share the P-substrate. The n-well and P-substrate are both collectors and bases at the same time. An upper resistor in a parallel connection between the Vdd and the base of the pnp bipolar transistor approximates the resistive path between the n-well and the contact to the Vdd supply while a lower resistor in a parallel connection between the base of the npn bipolar transistor and ground approximates the resistive path between the P-substrate and ground. A cascade reaction triggered by a small current across the resistors can forward bias the bipolar transistors and exponentially increase the current until the current is limited by the resistance of the circuit between the Vdd and ground. This condition is called a “latchup.” Latchups should be avoided in semiconductor circuits since it can cause a burn-out of a chip.

Guard rings are utilized to prevent a latchup in CMOS circuit designs. Guard rings are reverse biased PN junction diodes placed between the conduction paths of the parasitic p-n-p-n structures. Typically, guard rings consist of connections to both ground and power supply Vdd. A grounded guard ring is formed by a low-resistance P+ area that connects to ground. A power supply guard ring is formed by an n-well and an N+ region on the substrate that connects to the power supply Vdd. Positive N+ connection attracts electrons, and grounded P+ connection attracts holes. The cascade chain reaction of current amplification that leads to a latchup is thus prevented.

Latchup testing in a CMOS circuit is typically performed by injecting a trigger current of ±1-100 mA on the I/O pins to insure that latchup is not triggered under such conditions. Traditionally, guard rings are then manually placed as needed to prevent a latchup. Also, some automated processes of placing guard rings have been known in the art. One such example is shown in Ker et al., “Automatic Methodology for Placing the Guard Rings into Chip layout to Prevent Latchup in CMOS IC's,” IEDM Tech. Dig., 2001, pp. 113-116, wherein the guard rings are automatically placed around the power buses. While such automatic placement of guard rings tend to insure that sufficient level of protection against latchup is present in an IC, the large area that such guard ring structures occupy make the design layout less effective in the use of the semiconductor area.

With the continual scaling of semiconductor devices and with a limited number of I/O pads in present day IC's, the guard ring resistance has increased to make the guard ring structures less effective. The problem is that reduced guard ring width, reduced contact density (limited by bussing and manufacturing polish limits), and limitations on the bus location introduce a series resistance with the parasitic lateral npn bipolar transistor formed between the electrostatic discharge (ESD) device and the guard ring. As the series resistance increases with the guard ring (e.g. collector), the biasing of the parasitic lateral npn bipolar transistor is decreased. When the resistance is significant, the lateral bipolar is de-biased leading to the carriers traveling to other locations leading to latchup. Other factors also affect the effectiveness of guard ring structures in preventing a latchup in IC circuits with small device dimensions. These factors include contact density, guard ring resistance, bus resistance, and injection source location dependency.

Due to the general degradation of the effectiveness of the guard rings, neither manual placement of guard rings nor automatic placement of guard rings based on the availability of power bus is sufficient to achieve a high level of latchup protection with a minimum semiconductor space usage. Manual placement of guard rings, which tend to be area-effective, is prone to missing some the complexities affecting the effectiveness of guard rings as well as being time-consuming. Automatic placement of the guard rings based on the availability of power buses nearby tend to place more than enough guard rings thus use more semiconductor area than necessary to provide sufficiently high level of latchup protection.

Therefore, there exists a need for a methodology for automatically placing guard rings in a more area-efficient yet effective way.

There exists another need to control the path resistance between an electrostatic discharge (ESD) device and a guard ring.

There exists yet another need to provide an alternate design option when the path resistance exceeds a preset limit.

### SUMMARY OF THE INVENTION

To address the needs described above, the present invention provides a design structure for an IC design in which parameters for determining sufficiency of protection are checked against latchup, verifying the parameters by comparing them against specifications, and providing at least one re-design option to bring out-of-spec parameters into compliance with the specification. A design structure employing such an optimized guard ring is also provided.

According to an aspect of the present invention, the following steps are used to optimize the IC design to insure that the final design has sufficient protection against latchup.
(a) Each injection source is identified with an “injection shape.”
(b) The structures forming parasitic bipolar transistors between the injection shape and a guard ring are identified.
(c) The path resistance value between the structures forming parasitic bipolar transistors and a corresponding power supply pad is calculated.
(d) Based on specifications, a maximum resistance number for each of the path resistance value calculated above is defined.
(e) Each of the path resistance value is checked against the corresponding maximum resistance number.
(f) For each of the path resistance value that exceeds the corresponding maximum resistance number, a redesign is performed on at least one of the circuit elements affecting the path resistance value.
(g) The steps (c) through (f) are repeated until each of the path resistance value is less than the corresponding maximum resistance number.

According to another aspect of the present invention, to reduce the path resistance value that exceeded the corresponding maximum resistance number through a redesign, the redesign as described in step (f) above utilizes at least one option from the following:

1. Adjusting spacing of the guard ring to injection shape.

2. Widening the guard ring.

3. Increasing contact density.

4. Widening a power bus in a metal level.

5. Introducing new guard ring type.

6. Changing parameters of the guard ring PCell.

7. Decreasing the size of the ESD network.

Most of the steps described in the above methodology can be automated using a computer program. Thus, an automated system for checking, verifying, and optimizing a guard ring design is enabled though controlling the path resistance value from the components of parasitic bipolar transistor to the power supply and to ground.

According to yet another aspect of the present invention, a design structure embodied in a machine readable medium for designing, manufacturing, or testing a design is provided. The design structure comprising:

A first data representing structures forming parasitic bipolar transistors and a corresponding power supply pad;

a second data representing a guard ring in a semiconductor chiplet;

a third data representing a first circuit located inside the guard ring;

a fourth data representing a second circuit located outside the guard ring;

a fifth data representing guard ring contacts directly contacting the guard ring; and

a sixth data representing a power bus directly contacting the guard ring contacts, wherein a path resistance value between the structures forming parasitic bipolar transistors and the corresponding power supply pad is designed to be less than or equal to a preset corresponding maximum resistance number.

The design structure may further comprising one or more of the following:

a seventh data representing a chiplet guard ring, wherein the chiplet guard ring encloses the guard ring, the first circuit, and the second circuit;

an eighth data representing a first power bus directly connected to the first circuit; and

a ninth data representing a first power pad directly connected to the first power bus and located outside the guard ring;

a tenth data representing a second power bus directly connected to the second circuit; and

an eleventh data representing a second power pad directly connected to the second power bus and located outside the guard ring.

According to still another aspect of the present invention, a method of forming a design structure embodied in a machine readable medium for designing, manufacturing, or testing a design is provided. The method comprises:

providing a design structure comprising:
a first data representing structures forming parasitic bipolar transistors and a corresponding power supply pad;
a second data representing a guard ring in a semiconductor chiplet;
a third data representing a first circuit located inside the guard ring;
a fourth data representing a second circuit located outside the guard ring;
a fifth data representing guard ring contacts directly contacting the guard ring; and
a sixth data representing a power bus directly contacting the guard ring contacts;

calculating a path resistance value between structures forming parasitic bipolar transistors and a corresponding power supply pad;

checking the path resistance value against a corresponding maximum resistance number; and

performing a redesign on at least one of the circuit elements affecting the path resistance value if the resistance value exceeds the corresponding maximum resistance number.

### BRIEF DESCRIPTION OF THE DRAWINGS

FIG. 1 shows a flow chart for the design methodology for optimized guard ring design according to the present invention.

FIG. 2 shows an exemplary guard ring structure that the present invention can be used on.

FIG. 3 is a flow diagram of a design process used in semiconductor design and manufacture according to the present invention.

### DETAILED DESCRIPTION OF THE INVENTION

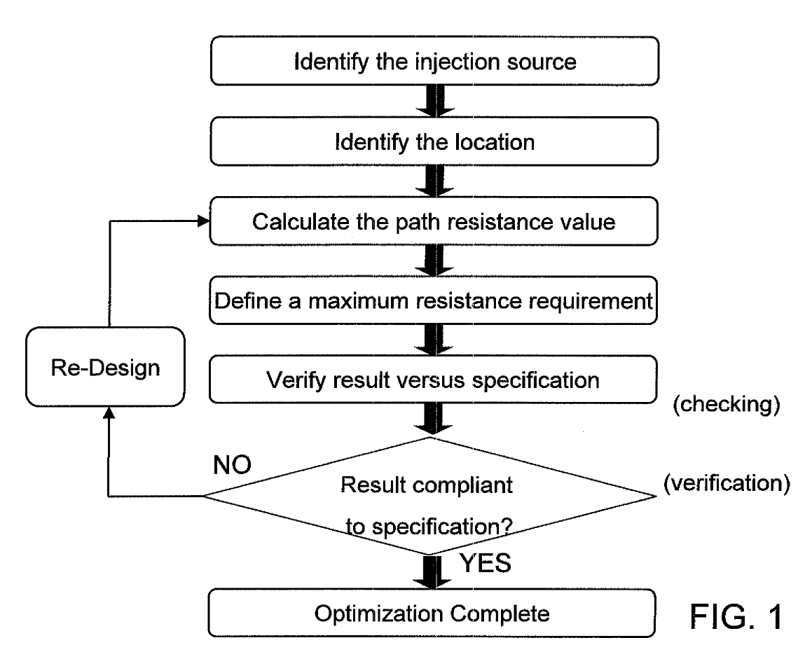

The present invention is herein described in detail with accompanying figures. Referring to FIG. 1, a flowchart showing the overall design methodology for optimizing guard ring design according to the present invention is shown.

According to the present invention, the injection sources are defined with an “injection shape.” There are two types of injection sources. Injection sources of the first type are the physical locations at which the positive supply voltage network makes physical contact with the N+ doped contact region within the n-well that contains a PFET. Injection sources of the second type are the physical locations at which the ground network makes physical contact with the P+ doped contact region within the P-substrate that contains an NFET. The injection sources of the first type are characterized in the design layout by a feature containing a Vdd contact to the N+ doped contact region and an adjacent PFET. Such a feature is defined as an “injection shape,” which means a circuit element that may potentially introduce an injection of an initial current to trigger a latchup. Similarly, the injection sources of the second type are characterized in the design layout by another feature containing a ground contact to the P+ doped contact region and an adjacent NFET. This feature is also defined as another “injection shape.” According to the present invention, all such elements are marked as injection shapes. Preferably, but not necessarily, other criteria for identifying injection shapes more accurately and effectively may be introduced to an injection shape recognition algorithm.

Once each injection shape is identified, the structures forming parasitic bipolar transistors between the injection shape and a guard ring are identified. The dimensions of the components of each parasitic bipolar transistor are calculated from the design layout. Of special importance is the location of the base of the parasitic bipolar transistor. In a CMOS circuit built on a P-substrate, the base of a parasitic lateral bipolar pnp transistor is the n-well in which the drain of a PFET is located and the base of a parasitic lateral bipolar npn transistor is the P-substrate in which the source of an NFET is located. Preferably but not necessarily, the structure recognition algorithm of FIG. 1 may include other filters to identify key structural components for optimizing the design for prevention of latchup while ignoring inconsequential structural components that do not affect latchup mechanism substantially.

In the next step depicted in FIG. 1, the path resistance value is measured between the structures forming parasitic bipolar transistors and a positive power supply pad or a ground pad. For the description of the present invention, the ground pad is also considered a power supply pad, which happens to supply the voltage of zero volts. Of special importance is the path resistance value between the base of a parasitic lateral bipolar pnp transistor and the positive power supply pad and the path resistance value between the base of a parasitic lateral bipolar npn transistor and the ground pad. The power supply pad associated with the selected component of the parasitic bipolar transistor for the parasitic resistors as described above is called the “corresponding” power supply pad. In other words, based on the structure of the parasitic circuit described above, once a structural component of the parasitic bipolar transistors is identified, the power supply pad “corresponding” to that structural component is determined automatically. Path resistance values can be calculated by extracting the dimensions and resistivity of the material from the design layout with an automated path resistance extraction algorithm. The path resistance value includes all components of resistance in the path between the two ends including the resistance of the guard ring, the resistance of the contacts, and the resistance of the power bus or the ground bus.

In a next step, a maximum resistance requirement for the path resistance is derived, or “defined” based on the specifications for protection against latchup and the forward active state of the parasitic lateral bipolar transistor. Preferably, the specifications for protection against latchup include the latchup specifications by Joint Electronic Device Engineering Council (JEDEC). Optionally, the specifications may include further margin to the JEDEC specifications for increased reliability of the IC products. This process can also be automated in a maximum resistance requirement definition algorithm.

The calculated path resistance value is then compared with the corresponding maximum resistance value for each component of the parasitic bipolar transistors. This is a numeric comparison of two values for each comparison and can readily be automated.

A path resistance value that is under the corresponding maximum resistance requirement verifies the portion of the design pertaining to the corresponding path resistance value. A path resistance values that exceed the corresponding maximum resistance value requirement identifies, or “flags,” a components of the parasitic bipolar transistor that needs a redesign. Typically some components are verified while some other components are flagged for redesign at this verification stage.

According to the present invention, the flagged components of the parasitic bipolar transistors and the guard ring are redesigned to reduce the path resistance values. After the redesign, the calculation of the new path resistance values, corresponding redefinition of the corresponding maximum resistance requirement if applicable, the comparison and reverification of the design follows. Since a redesign of one portion may indirectly affect another portion, reverification of all components of the design is in general necessary. Optionally, however, an algorithm may exclude reverification of a portion of a design if the redesign is deemed to have a minimal impact on the unaltered portion of the design. This iteration process can also be automated.

Several options exist for redesign of components of the parasitic bipolar transistors and the guard ring. At least one method is employed according to the present invention for each component that produced a falling path resistance value in the prior round of checking and verification. However, more than one method may be simultaneously be used during a redesign. The redesign part of this methodology can also be automated.

Several redesign methods are available according to the present invention during the redesign stage which comprise:

1. Adjusting spacing of the guard ring to injection shape.

2. Widening the guard ring.

3. Increasing contact density.

4. Widening a power bus or a ground bus in a metal level.

5. Introducing new guard ring type.

6. Changing parameters of the guard ring PCell.

7. Decrease the size of the ESD network to decrease the injection level.

The first method of adjusting the guard ring spacing is used to increase the gain of a parasitic lateral bipolar transistor. Such an increase in the gain of the bipolar transistor can compensate for the high path resistance value from a component of the bipolar transistor to a power supply pad.

The second method of widening the guard ring reduces the resistance of the guard ring itself, thereby reducing the path resistance value.

The third method of increasing the contact density decreases the resistance of the contacts to the N+ doped contacts in the n-well or the resistance of the contacts to the P+ doped contacts in the P-substrate, thereby reducing their contribution to the path resistance value.

The fourth method of widening a power bus in a metal level decreases the resistance of the power bus so that their contribution to the path resistance value is also reduced. As mentioned above, the ground pad is also considered a power supply and therefore, the ground bus is also considered a power bus, which happens to supply zero volts. The finite width of the physical power bus structure results in a finite resistance and a finite voltage deviation in the circuit from the supplied voltage at the power supply pad. By widening the power bus, their contribution to the path resistance value is also decreased.

The fifth method of introducing a new guard ring type substitutes an existing guard ring structure with a new one. Typically, guard rings occupy a significant area of a semiconductor substrate and therefore they are designed with maximum area efficiency achievable during the design phase to use as little semiconductor area as possible. If one type of guard ring does not provide sufficient protection against latchup, a larger guard ring may be substituted at the expense of less area efficiency.

The sixth method of changing parameters of guard ring PCell adjusts the design of the PCell used in the guard ring design. PCells are programmable component layouts that may be stretched through parameter inputs. The PCell is designed in accordance with process design rules, and, when placed, the component complies with the design rules by construction. The design rules may be input into the database for access by all tools within the framework. These rules are input into the PCell as variables that enable easy migration to technologies with a database update. Layout options can be passed to the PCell as optional parameters in the design. A discussion on the use of a PCell is provided in Harame et al., “Design automation methodology and rf/analog modeling for rf CMOS and SiGe BiCMOS technologies,” IBM J. RES & DEV., Vol. 47, No. 2/3, March/May 2003. By changing the built-in parameters in the PCells, the design is altered to be compliant to the specifications for protection against latchup.

The seventh method of decreasing the size of the ESD network can be employed to decrease the injection level according to the specifications since a smaller size of ESD networks have less probability of being subjected to an ESD event involving large charges.

The seven methods of redesign are used alone or in combination to rectify the portions of the design that were not compliant to the specification for protection against latchup during the previous round of checking and verification. As shown in FIG. 1, the processes can be reiterated until a satisfactory guard ring design finally passes all specifications.

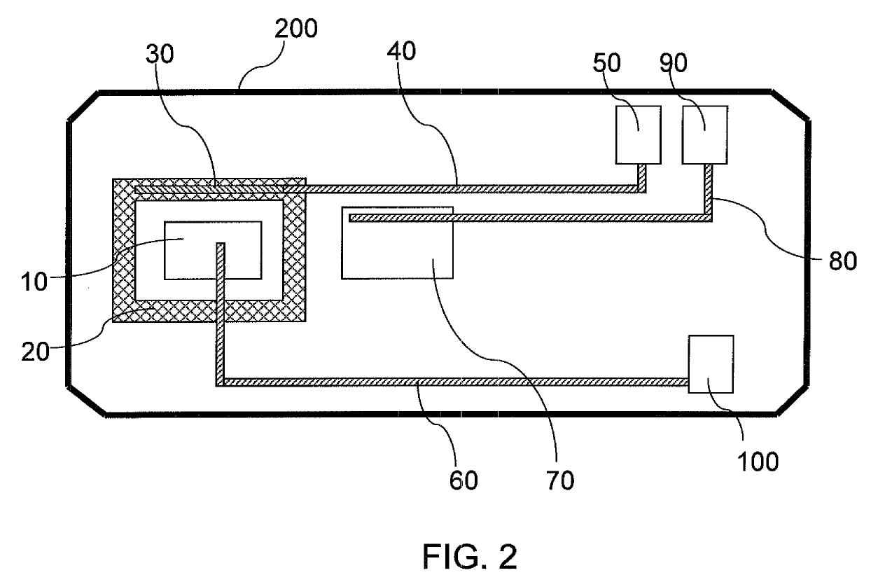

The implementation of the present invention results in an optimized guard ring structure. FIG. 2 is an exemplary guard ring structure for an IC chiplet containing a circuit A 10 placed within a guard ring 20 and a circuit B 70 placed outside the guard ring 20. Both Circuit A 10 and circuit B 70 are placed inside a chiplet guard ring 200. Circuit A 10 is powered by a Circuit A power bus 60 which is then connected to a Circuit A power pad 100. An I/O pad 90 is connected to a circuit B bus 80, which in turn is connected to circuit B 70. The guard ring 20 is contacted by guard ring contacts 30, which are connected to a power bus 40 extending to the power supply pad 50.

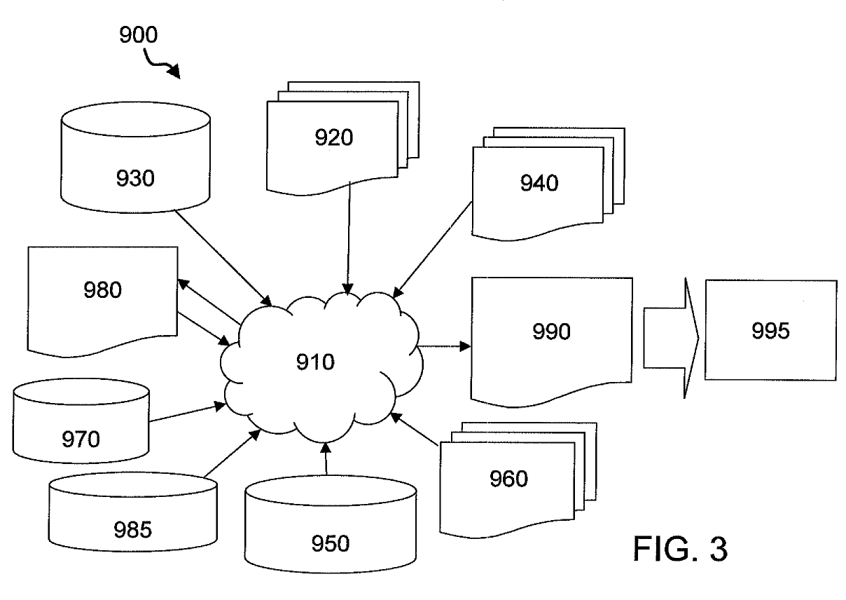

FIG. 3 shows a block diagram of an exemplary design flow 900 used for example, in semiconductor design and manufacturing. Design flow 900 may vary depending on the type of IC being designed. For example, a design flow for building an application specific integrated circuit (ASIC) may differ from a design flow for designing a standard integrated circuit component. Design structure 920 is preferably an input to a design process 910 and may come from an intellectual property (IP) provider, a core developer, or a design company, or may be generated by the operator of a design flow, or may come from other sources.

Design structure 920 comprises an embodiment of present invention as shown in FIG. 2 in the form of schematics or HDL, hardware description language (e.g. Verilog, VHDL, C, etc.) The design structure 920 may be contained on one or more machine readable medium. For example, design structure 920 may be a text file or a graphical representation of an embodiment of the invention as shown in FIG. 2.

Design process 910 preferably synthesizes (or translates) an embodiment of the invention as show in FIG. 2 into a netlist 980, where netlist 980 is, for example, a list of wires, transistors, logic gates, control circuits, I/O, models, etc. that describes the connections to other elements and circuits in an integrated circuit design and recorded on at least one of machine readable medium. For example, the medium may be a CD, a compact flash, other flash memory, a packet of data to be sent via the Internet, or other networking suitable means. The synthesis may be an iterative process in which the netlist 980 is resynthesized one or more times depending on design specifications and parameters for the circuit.

The design process 910 may include using a variety of inputs; for example, inputs from library elements 930 which may house a set of commonly used elements, circuits, and devices, including models, layouts, and symbolic representations, for a given manufacturing technology (e.g., different technology nodes such as 32 nm, 45 nm, and 90 nm, etc.), design specifications 940, characterization data 950, verification data 960, design rules 970, and test data files 985 (which may include, for example, standard circuit design processes such as timing analysis, verification, design rule checking, place and route operations, etc. One of ordinary skill in the art of integrated circuit design can appreciate the extent of possible electronic design automation tools and applications used in the design process 910 without deviating from the scope and spirit of the present invention. The design structure of the present invention is not limited to any specific design flow.

Design process 910 preferably translates an embodiment of the invention as shown in FIG. 2, along with any additional integrated circuit deign or data (if applicable), into a second design structure 990. Design structure 990 resides on a storage medium in a data format used for the exchange of layout data of integrated circuits and/or symbolic data format (e.g., information stored in GDSII (GDS2), GL1, OASIS, map files, or any other suitable format for storing such design structures). Design structure 990 may comprise information such as, for example, symbolic data, map files, test data files, design content files, manufacturing data, layout parameters, wires, levels of metal, vias, shapes, data for routing though the manufacturing line, and any other data required by a semiconductor manufacturer to produce an embodiment of the invention as shown in FIG. 2. Design structure 990 may ten proceed to a stage 995 where, for example, design structure 990 proceeds to tape-out, is released to manufacturing, is released to a mask house, is sent to another design house, is sent back to a customer, etc.

While the invention has been described in terms of specific embodiments, it is evident in view of the foregoing description that numerous alternatives, modifications and variations will be apparent to those skilled in the art. Accordingly, the invention is intended to encompass all such alternatives, modifications and variations which fall within the scope and spirit of the invention and the following claims.

What is claimed is:

1. A design structure embodied in a machine readable medium for designing, manufacturing, or testing a design, said design structure comprising:
a first data representing structures forming parasitic bipolar transistors and a corresponding power supply pad;
a second data representing a guard ring in a semiconductor chiplet;
a third data representing a first circuit located inside said guard ring;
a fourth data representing a second circuit located outside said guard ring;
a fifth data representing guard ring contacts directly contacting said guard ring; and
a sixth data representing a power bus directly contacting said guard ring contacts, wherein a path resistance value between said structures forming parasitic bipolar transistors and said corresponding power supply pad is designed to be less than or equal to a preset corresponding maximum resistance number.

2. The design structure of claim 1, wherein said design structure comprises a netlist.

3. The design structure of claim 1, wherein said design structure resides on storage medium as a data format used for exchange of layout data of integrated circuits.

4. The design structure of claim 1, further comprising a seventh data representing a chiplet guard ring, wherein said chiplet guard ring encloses said guard ring, said first circuit, and said second circuit.

5. The design structure of claim 4, further comprising:
an eighth data representing a first power bus directly connected to said first circuit; and
a ninth data representing a first power pad directly connected to said first power bus and located outside said guard ring.

6. The design structure of claim 5, further comprising:
a tenth data representing a second power bus directly connected to said second circuit; and
an eleventh data representing a second power pad directly connected to said second power bus and located outside said guard ring.

7. A method of forming a design structure embodied in a machine readable medium for designing, manufacturing, or testing a design, said method comprising:
providing a design structure comprising:
a first data representing structures forming parasitic bipolar transistors and a corresponding power supply pad;
a second data representing a guard ring in a semiconductor chiplet;
a third data representing a first circuit located inside said guard ring;
a fourth data representing a second circuit located outside said guard ring;
a fifth data representing guard ring contacts directly contacting said guard ring; and
a sixth data representing a power bus directly contacting said guard ring contacts;
calculating a path resistance value between structures forming parasitic bipolar transistors and a corresponding power supply pad;
checking said path resistance value against a corresponding maximum resistance number; and
performing a redesign on at least one of the circuit elements affecting said path resistance value if said resistance value exceeds said corresponding maximum resistance number.

8. The method of claim 6, wherein said design structure further comprises a seventh data representing a chiplet guard ring, wherein said chiplet guard ring encloses said guard ring, said first circuit, and said second circuit.

9. The method of claim 8, wherein said design structure further comprises:
an eighth data representing a first power bus directly connected to said first circuit; and
a ninth data representing a first power pad directly connected to said first power bus and located outside said guard ring.

10. The method of claim 9, wherein said design structure further comprises:
a tenth data representing a second power bus directly connected to said second circuit; and
an eleventh data representing a second power pad directly connected to said second power bus and located outside said guard ring.

11. The method of claim 7, wherein said redesign on a least one of said circuit elements affecting said path resistance utilizes at least one method selected from the group consisting of the following:
adjusting the spacing between a guard ring and an injection shape;
widening said guard ring;
increasing contact density in said guard ring;
widening a power bus in a metal level;
introduce new guard ring types;
changing parameters of said guard ring PCell; and
decreasing the size of an ESD network.

12. The method of claim 7, further comprising identifying an injection source with an injection shape.

13. The method of claim 12, further comprising identifying structures forming parasitic bipolar transistors between said injection shape and a guard ring.

14. The method of claim 13, further comprising defining a maximum resistance number for said path resistance value based on specifications.

15. The method of claim 7, wherein at least one of said steps are repeated more than once.
